(19) United States
(12) Patent Application Publication
(10) Pub. No.: US 2015/0155175 A1
(43) Pub. Date: Jun. 4, 2015

(54) METHOD FOR THE METALLIZATION OF A POROUS MATERIAL

(71) Applicants: Commissariat A L'energie Atomique Et Aux Ene Alt, Paris (FR); STMicroelectronics SA, Montrouge (FR)

(72) Inventors: Aomar HALIMAOUI, La Terrasse (FR); Laurent VANDROUX, Le Cheylas (FR)

(73) Assignees: COMMISSARIAT A L'ENERGIE ATOMIQUE ET AUX ENE ALT, Paris (FR); STMICROELECTRONICS SA, Montrouge (FR)

(21) Appl. No.: 14/555,926

(22) Filed: Nov. 28, 2014

(30) Foreign Application Priority Data
Nov. 29, 2013 (FR) 13 61849

(51) Int. Cl. H01L 21/288; H01L 21/768

(52) U.S. Cl. CPC H01L 21/288; H01L 21/76879

(57) ABSTRACT

Metallization method for a porous material including deposition of a metallic material in the liquid phase using a solution containing metal ions, the conditions consisting of the solution temperature, the pH of the solution, and the concentration of metal ions in solution being chosen to result in a deposition rate of the metallic material less than or equal to 0.1 nm/min.

### TECHNICAL FIELD AND PRIOR ART

This description applies to the field of metalized porous structures and particularly porous structures based on a porous semiconducting material that has been filled with a metallic material.

It discloses a method of making a porous metalized structure with a better filling ratio and a more uniform distribution of the metallic material in the thickness of the structure.

It is known that a porous material can be metalized by an electrolytic deposition or electrodeposition technique that requires an input of electrical current or by a deposition method of the type commonly called “electroless” based on an auto-catalytic reaction.

The “Electrodeposition of metals into porous silicon” document by Jeske et al., Thin Solid films, 1995 describes different techniques for metallization of porous Si using Au, Cu or Ni.

FIG. 8 in this document shows that it is difficult to obtain a uniform distribution of metal throughout the thickness of the porous silicon, the metal tending to concentrate principally on the surface of the layer of porous Si.

This difficulty also becomes clear in the document “Different Behavior in immersion Plating of Nickel on Porous Silicon from Acidic and Alkaline Fluoride Media”, by Harraz et al., Journal of the Electrochemical Society, 2003, as shown in FIGS. 1 and 2. A sectional view of porous Si after an attempt has been made to fill the porous Si with gold or nickel shows that the metal has been distributed essentially on the surface of the Si layer.

The problem arises of finding a new method of metalizing a porous material by which the metal can penetrate through the entire thickness of the porous material and lead to a better distribution of the metal in the thickness of the porous material.

### PRESENTATION OF THE INVENTION

The invention firstly relates to a metallization method for a porous material by deposition of a metallic material in the liquid phase using a solution containing metal ions.

The invention requires a low deposition rate of a metallic material.

The conditions consisting of the deposition temperature, the pH of said solution and the concentration of metal ions in solution in which the porous material is dipped, are chosen jointly to result in a deposition rate of the metallic material equal to less than or equal to the order of 0.1 nm/min.

A deposition rate less than or equal to 0.1 nm/min can improve the filling of the porous material, and particularly can give a total filling of the porous layer or the porous substrate.

Such a deposition rate can also result in a uniform filling of the metallic material in the thickness of the porous material.

The use of a liquid phase deposition in particular has the advantage of being much less expensive than gas phase deposition processes.

The porous material that is metalized may be in the form of a substrate or a layer with a thickness of several hundred μm.

The porous material that is metalized may be a material with open porosity.

The porous material that is metalized may be a semiconducting material or a zeolithic type micro-porous mineral material

The porous material that is metalized may advantageously be Si.

The concentration of metal ions is preferably chosen to be less than or equal to a predetermined threshold concentration.

The molar concentration of metal ions in solution is preferably less than 0.1 M so as to achieve a deposition rate of the metallic material of less than 0.1 nm/min.

The temperature is preferably chosen to be less than or equal to a predetermined temperature threshold.

The temperature of the chemical bath used and containing the deposition solution may be chosen within the [0° C.; 25° C.] interval and will preferably be close to 0° C., to achieve a deposition rate of the metallic material of less than 0.1 nm/min.

The pH of the deposition solution is also preferably an acidic or low a pH.

The pH of the solution is adjusted as a function of the temperature and the concentration of metal ions while preventing dissolution of the porous material.

The pH of the deposition solution may be chosen to be less than 7 and preferably less than or equal to 6, and advantageously less than or equal to 4, so as to achieve a deposition rate of the metallic material of less than 0.1 nm/min.

The deposition solution may then be a solution containing Ni+ or Cu²⁺ or Au³⁺ or Ag⁺ ions in order to metalize the porous Si.

The deposition solution may include a surfactant so as to improve filling.

As a variant, the material to be metalized can be placed in a solution containing a surfactant before deposition of the metallic material.

This invention is applicable to metallization of porous structures in which the porosity is composed of pores or even cracks or trenches.

The invention also relates to a method of fabrication of a microelectronic device comprising a metallization method according to any one of the previous claims.

### BRIEF DESCRIPTION OF THE DRAWINGS

This invention will be better understood after reading the description of example embodiments given purely for information and in no way limitative with reference to the appended drawings in which:

FIGS. 1A-1B show porosification of a semiconducting substrate,

FIGS. 2A-2B show curves of the deposition rate of Ni in the liquid phase as a function of the deposition temperature for a given pH of 6 of the deposition solution containing Ni+ ions, and a given molar concentration of 0.2 M in Ni+ ions in the deposition solution,

FIG. 3 shows a curve showing the deposition rate of Ni in the liquid phase as a function of the pH of the deposition solution used containing Ni+ ions,

FIGS. 4A-4B show curves of the deposition rate of Ni in the liquid phase as a function of the deposition temperature for a given pH of 4 of the deposition solution containing Ni+ ions, and a given molar concentration of 0.2 M in Ni+ ions in the deposition solution,

FIG. 5 shows a curve showing the deposition rate of Ni in the liquid phase as a function of the molar concentration of Ni+ ions in the deposition solution used,

FIG. 6 shows a curve of the deposition rate of Ni in the liquid phase for a given pH of 4 of the deposition solution used and containing Ni+ ions and a molar concentration of Ni+ ions less than a threshold concentration of 0.1 M,

FIGS. 7A-7B show Ni concentration curves within the thickness of a layer of porous Si, for a deposition rate according to the invention equal to less than 0.1 nm/min, and for a deposition rate of 7 nm/min respectively,

FIGS. 8A-8C show different types of porous structures composed of crack porosities in which a metallization method according to the invention could be applied.

As is usual in drawings of semiconducting structures, the various sectional views are not shown to scale. The various parts shown in the figures are not necessarily all at the same scale to make the figures more easily readable.

### DETAILED PRESENTATION OF PARTICULAR EMBODIMENTS

An example method according to the invention for metallization of a porous structure will now be disclosed.

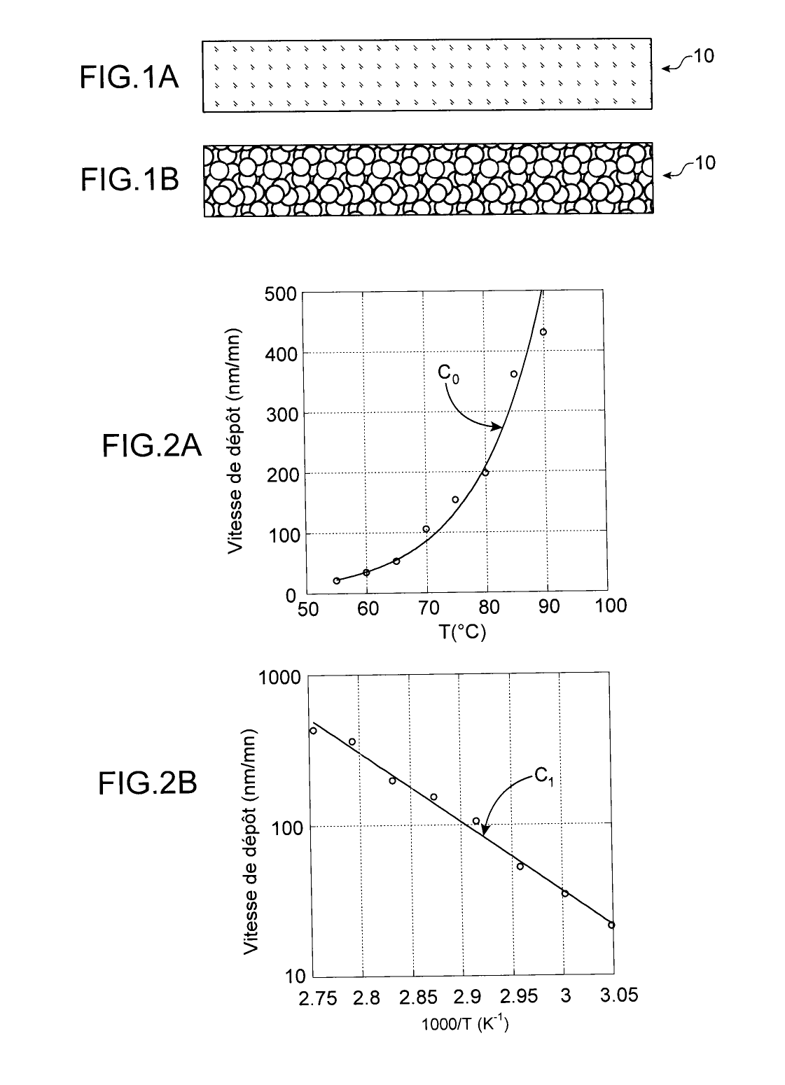

The initial material for this method may be a solid substrate 10 based on a semiconducting material (FIG. 1A), for example such as Si, that is made porous (FIG. 1B), for example by means of an electrochemical etching process in a hydrofluoric acid (HF) medium.

The substrate 10 may be doped with P type doping, with a doping level of between 10¹⁵ cm⁻³ and 10¹⁹cm⁻³. In this example, the doping level may for example be of the order of 10¹⁹cm⁻³. For this doping level, the porosity of the porous silicon layer may be between 20% and 85% and adjusted as a function of electrochemical conditions. The porosity of the substrate 10 may for example be of the order of 80% and its thickness may for example be of the order of 1 μm.

The diameter, also called the critical pore diameter, is between several nanometers and several tens of nanometers. In this example, the diameter of the pores may be greater than 5 nm, for example of the order of 10 nm. The method according to the invention is particularly applicable to filling small pores, i.e. with a critical dimension or diameter of less than 20 nm.

The porous material surface may be activated prior to metallization of the porous substrate 10.

This can be done by a first dip in an SnCl₂ based solution, for example with a molar concentration of the order of 0.3M and a duration of the order of 2 minutes.

Rinsing and a second dip may be made in a solution possibly based on PdCl₂, for example with a molar concentration of the order of 2*10⁻³ M, for example with a duration of the order of 1 minute.

These dipping steps help to modify and activate the surface of the porous material.

A surfactant may also be applied to the porous material before the metallization step in order to reduce the surface tension of the porous material and thus increase its wettability. The surfactant may be dispensed on the substrate 10 by means of a nozzle or it may be in the form of a bath in which the substrate 10 is immersed. The surfactant may for example be ethanol. Other surfactants such as methanol, acetic acid, sodium stearate, benzene sulfonate or an organic solvent may also be used.

Advantageously, the surfactant may be included in the deposition solution to metalize the porous material.

After immersion in the surfactant, the substrate 10 can then be rinsed without drying.

The next step is to deposit the metallic material in the liquid phase, the infill metallic material being in the form of metal ions present in a liquid deposition solution.

This deposition solution may for example include an NiSO₄ based solution containing Ni+ metal ions when it is required to metalize the porous substrate using Nickel.

Other metals such as gold (Au), copper (Cu), silver (Ag) may be deposited by replacing the Ni salt (NiSO₄) by a salt of the metal to be deposited. For example, metallization with Au can be done using a solution of Aucl₃. Metallization with Cu may for example be done using a solution of CuSO₄, whereas metallization with Ag can be done for example using a solution of Ag₂SO₄.

The molar concentration of Ni+ ions in this solution is preferably less than 0.1M and may for example be of the order of 0.05 M. A reducing agent, for example such as sodium hypophosphite Na₂H₂PO₂ with a molar concentration for example of the order of 0.1 M may also be integrated into the deposition solution, as well as a complexing agent for example such as lactic acid CH₃CHOHCO₂ with a molar concentration of 0.2 M.

An acid, for example such as diluted sulfuric acid H₂SO₄, can be integrated in order to adapt the pH of the deposition solution and particularly to make this solution acidic.

Rinsing and drying steps can then be applied.

The inventors have discovered that in order to fill the porous substrate uniformly and preferably throughout its entire thickness, according to the invention, the metallic material is deposited at a very low deposition rate, particularly within a range of deposition rates less than or equal to 0.1 nm/min.

Such a deposition rate range is not easy to obtain, particularly in the liquid phase.

The inventors have discovered that such a range of deposition rate less than or equal to 0.1 nm/min can be achieved by making a combined adaptation of conditions consisting of the pH, solution temperature and concentration of metal ions in solution.

The temperature of the deposition solution is one of the parameters to be adapted to reach a low deposition rate, a low deposition temperature, i.e. at least less than 25° C. and close to 0° C. being conducive to a low deposition rate.

FIGS. 2A and 2B give examples of curves C₀, and C₁ showing the variation in the deposition rate as a function of the temperature, obtained for an example deposition solution with a molar concentration in NiSO₄ of the order of 0.2 M, a molar concentration in sodium hypophosphite of the order of 0.3 M, a molar concentration in lactic acid of the order of 0.25 M, with a pH of the order of 6.

These curves C₀ and C₁ show a reduction in the deposition rate with the temperature.

To achieve a deposition rate of less than 0.1 nm/min, a concomitant adjustment of parameters other than temperature is thus required.

The pH is another of the parameters to be adapted to achieve a low deposition rate. A low pH is conducive to a low deposition rate.

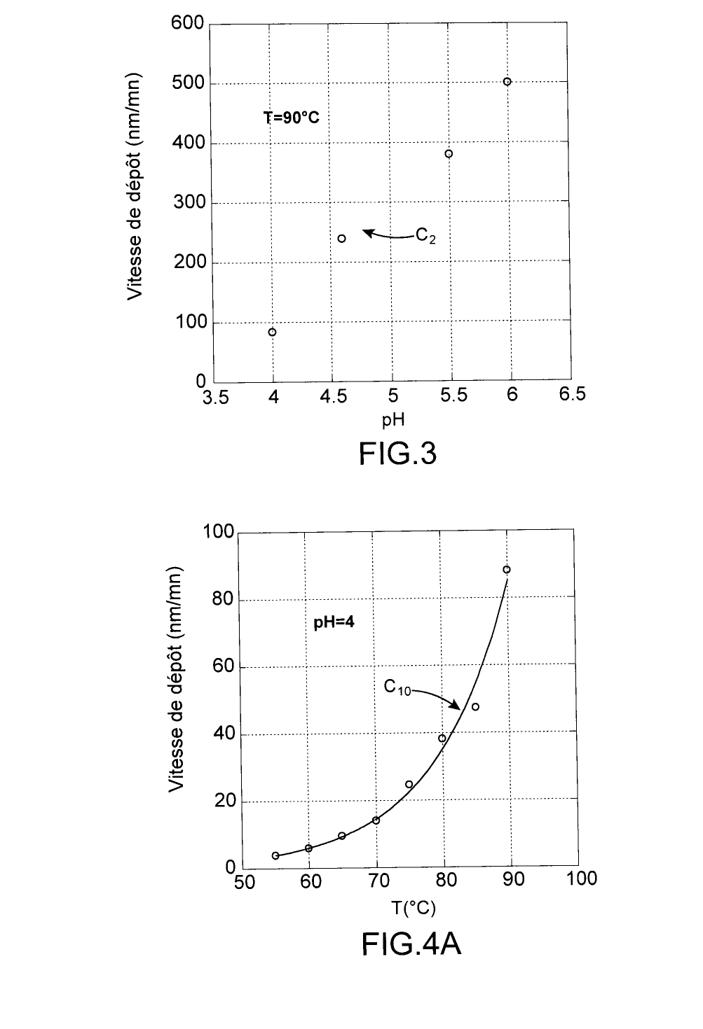

FIG. 3 shows an example of a curve C₂ showing the variation of the deposition rate as a function of the pH of the deposition solution for an example deposition solution with a molar concentration in NiSO₄ of the order of 0.2 M, a molar concentration in sodium hypophosphite of the order of 0.3 M, a molar concentration in lactic acid of the order of 0.25 M, a temperature of the order of 90° C. This curve C₂ shows a reduction in the deposition rate with the pH.

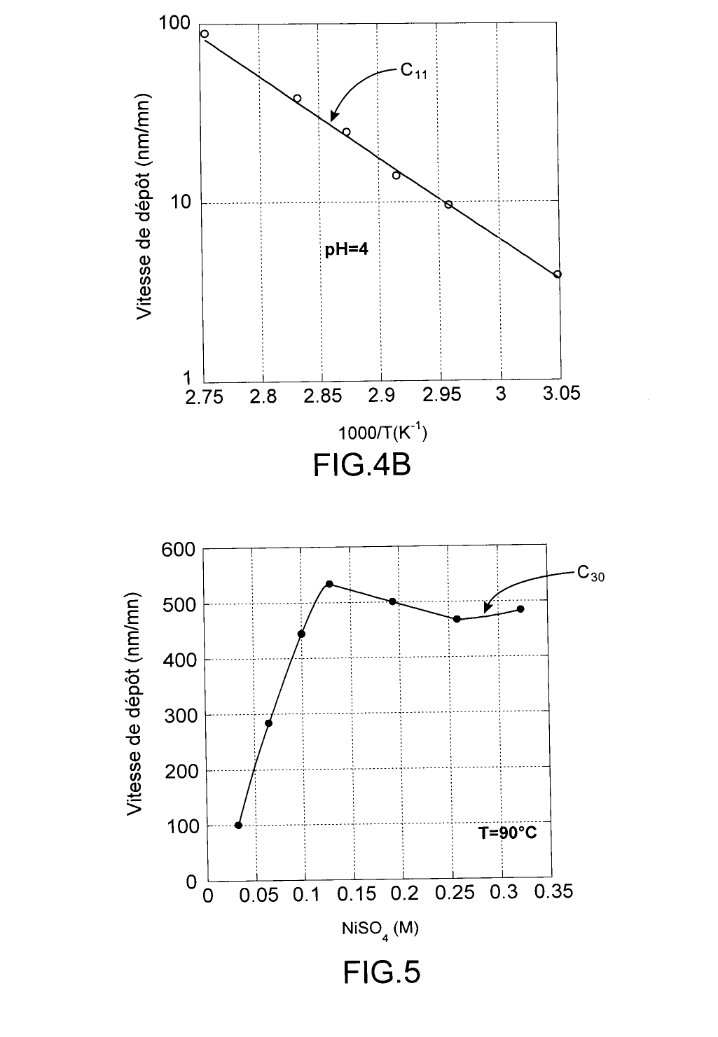

FIGS. 4A and 4B give examples of curves C₁₀, and C₁₁ showing the variation of the deposition rate as a function of the temperature, obtained for the example deposition solution given above with a molar concentration in NiSO₄ of the order of 0.2 M, a molar concentration in sodium hypophosphite of the order of 0.3 M, a molar concentration in lactic acid of the order of 0.25 M and a pH of the order of 4, less than the value in the example in FIGS. 2A-2B. These curves C₁₀ and C₁₁ show a deposition rate that reduces with the temperature and that remains less than the deposition rate in the example in FIGS. 2A-2B. An extrapolation of these curves shows that a deposition rate of the order of 0.15 nm/min can be achieved at a temperature of 25° C. with a pH=4.

In order to achieve a deposition rate of less than 0.1 nm/min, in addition to adapting the temperature and the pH, the concentration of metal ions is adjusted concomitantly. In this example, the pH is preferably chosen to be less than 7, and preferably less than 6 so as to obtain a low deposition rate while preventing dissolution of the porous Si.

FIG. 5 shows a curve C₃₀ showing the variation of the deposition rate as a function of the concentration of Ni+ metal ions for an example metallic deposition solution based on NiSO₄ with a pH of 4, at a temperature of the order of 90° C.

This curve C₃₀ shows that the deposition rate remains constant above a threshold concentration that in this example is of the order of 0.1 M.

A large reduction in the deposition rate is observed below this threshold concentration.

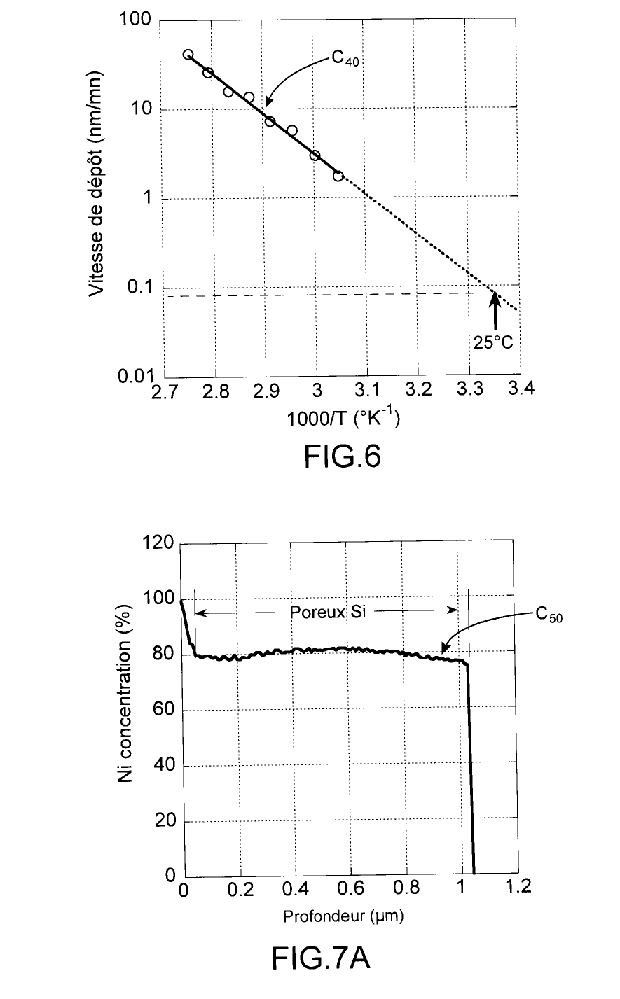

FIG. 6 shows a curve C₄₀ showing the variation of the deposition rate as a function of the temperature for an example deposition solution based on NiSO₄ with an acidic pH equal to 4, a concentration of the NiSO₄ metal solution of the order of 0.05 M thus chosen below the value of the threshold concentration, a molar concentration in sodium hypophosphite of the order of 0.1 M, a molar concentration in lactic acid of the order of 0.2 M, and a pH equal to 4 adjusted by a dilution of H₂SO₄.

With such conditions for the pH, concentrations of metal ions in the deposition solution and temperature, the deposition rate is of the order of 0.08 nm/min that is therefore less than 0.1 nm/min.

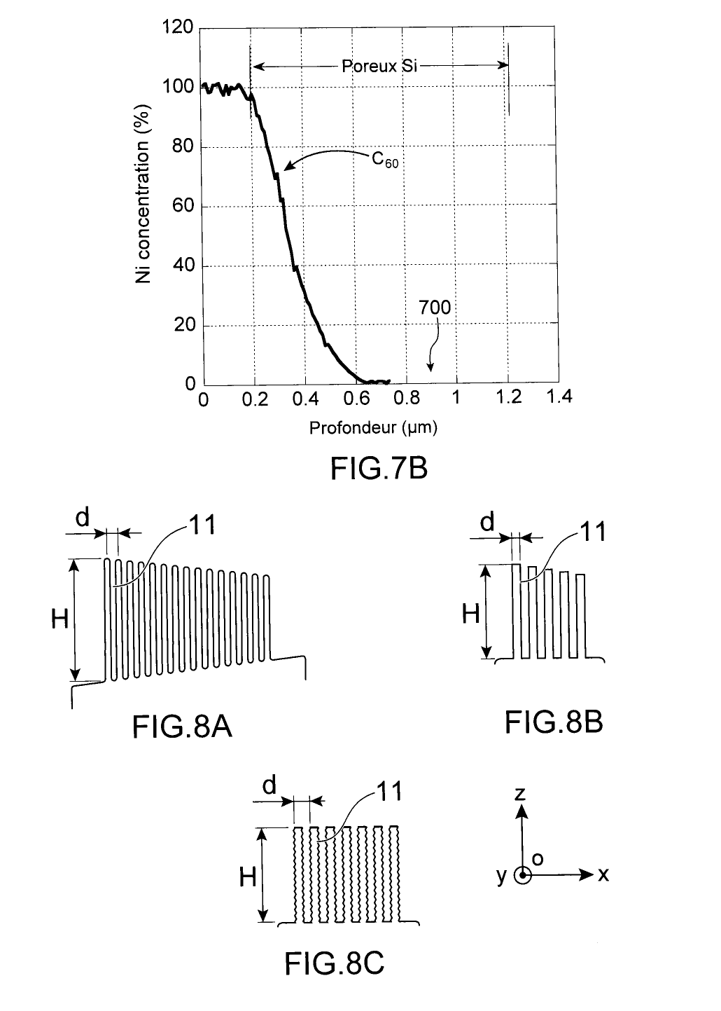

FIG. 7A shows an example curve C₅₀ obtained by Rutherford Backscattering Spectroscopy (RBS) for an Ni concentration profile in a layer of porous Si metalized using the method according to the invention as a function of the depth in the layer of porous Si.

This metalized layer is of the type of substrate 10 described above with P+ type doping, 1 μm thick, with a porosity of the order of 80% and pore diameters of the order of 10 nm. The deposition of metallic material made under deposition conditions consisting of temperature 25° C., pH equal to 4, molar concentration of metal ions in the NiSO₄ metal solution, adapted to obtain a deposition rate of less than 0.1 nm/min. The profile was measured after a stay of the Si layer in the deposition solution for approximately 2 hours.

The pores are completely filled after this duration of 2 h. The surface of the pores will be coated with metal for a shorter duration (i.e. less than 2 h).

Curve C₅₀ shows infill of the Si layer by Ni over its entire thickness and a uniform Ni concentration throughout the entire thickness of the layer of metalized Si.

For comparison, curve C₆₀ in FIG. 7B also obtained by RBS, shows a case in which a deposition rate of more than 0.1 nm/min is used, particularly of the order of 7 nm/min, the deposition temperature having been chosen higher than in the example in FIG. 7A. The deposition of metallic material was made at a deposition temperature of 70° C., the profile having been measured after residence of the Si layer in the deposition solution for approximately 30 minutes. This curve C₆₀ shows non-uniform filling with Ni and an absence (cross-hatched portion 700) of Ni at a depth of more than 0.8 μm in the Si layer with a total thickness of 1 μm.

A variant example of the metallization method according to the invention may include the following sequence of steps:

Step 1: A porous substrate is immersed in a cold solution of ethanol, in other words at a temperature less than the ambient temperature that may be within the [0° C.; 25° C.] interval and preferably close to 0° C.;

Step 2: The porous substrate is rinsed in cold water, for example in water at a temperature within the [0° C.; 25° C.] interval and preferably close to 0° C.;

Step 3: The porous substrate is immersed in the deposition solution held at low temperature, i.e. within the [0° C.; 25° C.] interval and preferably approximately 0° C.

Step 4: The deposition solution is removed from the surface of the substrate 10 by centrifuging;

Step 5: the solution trapped inside the pores forms the source of the Ni deposition. The solution thus trapped in the pores may then be heated, by immersing the substrate in warm water, for example above 25° C.

With this possible embodiment, the material to be metalized is placed in the deposition solution at a low temperature close to 0° C. and under conditions in which a deposition can be initiated at a deposition rate of the metallic material less than or equal to 0.1 nm/min. Centrifuging is then done in order to remove the deposition solution from the surface of the porous material, while keeping this solution inside the pores.

The porous material is dipped once again in a bath at a temperature of more than 25° C. so that the deposition rate is faster in this case.

In this case, there is no risk of clogging the pore inlets. Since the solution is already inside the pores, the deposition is made uniformly throughout the thickness of the substrate.

This sequence of steps that has just been described may possibly be repeated one or several times.

As a variant of step 5, the substrate is placed on a heating support or a retaining plate (chuck) while water is poured on the substrate.

A method according to the invention is particularly applicable to porous Si but it may also be applied to filling of other types of porous materials, for example for which a porosity is as shown in FIGS. 8A-8C, with crack porosities 11 or is formed by trenches 11 with a large aspect ratio H/d where H is the crack depth (measured along the z axis of the [O,x,y,z] orthogonal system in FIGS. 8A-8C), and d is the critical dimension or width of the cracks (measured in the [O,x,y] plane).

The aspect ratio H/d of cracks 11 may for example be at least 100, for example of the order of 1000.

The metallization method may in particular be applicable to metallization of structures obtained by lithography and etching as used in microelectronic systems or microsystems.

A low deposition rate of the metallic material, and particularly a deposition rate of less than or equal to 0.1 nm/min, is applied in each of the example methods described above.

Such a deposition rate may be determined for example by means of images obtained for example by scanning microscopy on which thicknesses of metallic material deposited at different instants are measured and are then related to a time elapsed between these instants.

Another method of measuring the deposition rate may for example be to weigh the porous structure on which the deposition is made at different instants, and then relating the difference in mass obtained to a time elapsed between these instants.

1. Metallization method for a porous material including deposition of a metallic material in the liquid phase on the porous material, using a solution containing metal ions, the conditions consisting of the solution temperature, the pH of the solution, and the concentration of metal ions in solution being chosen to result in a non-zero deposition rate of the metallic material equal to less than or equal to the order of 0.1 nm/min.

2. Method according to claim 1, in which the porous material is Si.

3. Method according to claim 1, in which the pH of the solution is less than 7.

4. Method according to claim 1, in which the molar concentration of metal ions in solution is less than 0.1 M.

5. Method according to claim 1, in which the deposition temperature is chosen within the [0° C.; 25° C.] interval.

6. Method according to claim 1, in which the metal solution comprises a surfactant.

7. Method according to claim 1, in which the substrate is immersed in a solution containing a surfactant before the deposition of the metallic material.

8. Method according to claim 1, in which the metal ions are Ni⁺, or Ag⁺, or Au³⁺, or Cu²⁺ ions.

9. Method according to claim 1, in which the porous material is nano-porous with pore diameters between 5 nm and 20 nm.

10. Metallization method for a porous material comprising deposition of a metallic material in the liquid phase on the porous material using a solution containing metal ions, characterized in that the conditions consisting of the solution temperature, the pH of the solution and the concentration of metal ions in solution are chosen to result in a deposition rate of the metallic material less than or equal to 0.1 nm/min.

11. Method according to claim 10, in which:
pH of the solution is less than 7,
molar concentration of metal ions in solution is less than 0.1 M,
deposition temperature is chosen within the [0° C.; 25° C.] interval.

12. Method according to claim 11, in which the metal solution comprises a surfactant.

13. Method according to claim 11, in which the substrate is immersed in a solution containing a surfactant before the deposition of metallic material.

14. Method according to claim 11, in which the porous material is Si.

15. Method according to claim 14, in which the metal ions are Ni⁺, or Ag⁺, or Au³⁺, or Cu²⁺ ions.

16. Method according to claim 14, in which the porous Si is nano-porous with pore diameters between 5 nm and 20 nm.
